(19) United States
(12) Patent Application Publication
(10) Pub. No.: US 2026/0369508 A1
(43) Pub. Date: Nov. 19, 2026

(54) DEVICE FOR A FUSE BOX OF A MOTOR VEHICLE, FUSE SYSTEM, MOTOR VEHICLE, AND METHOD FOR OPERATING A DEVICE FOR A FUSE BOX OF A MOTOR VEHICLE

(71) Applicant: VOLKSWAGEN AKTIENGESELLSCHAFT, Wolfsburg (DE)

(72) Inventors: Martin DÖRING, Braunschweig (DE); Ralf MILKE, Erkerode (DE)

(21) Appl. No.: 19/475,943

(22) PCT Filed: Apr. 18, 2024
(86) PCT No.: PCT/EP2024/060564

§ 371 Date: Oct. 16, 2025

(30) Foreign Application Priority Data
Apr. 25, 2023 (DE) 10 2023 203 791.2

(51) Int. Cl. H01H 85/02; B60R 16/023; G07C 5/08

(52) U.S. Cl. CPC H01H 85/0241; B60R 16/0239; G07C 5/0825

(57) ABSTRACT

A device for a fuse box of a motor vehicle, at least one fuse element couplable to the fuse box of the motor vehicle and allocatable to an electrical component of the motor vehicle, a control unit, and a display unit, wherein the at least one fuse element is configured to assume a triggered state or a closed state, wherein the control unit is configured to detect the state of the at least one fuse element and transmit the state to the display unit, wherein the display unit configured to display a change in the state of the at least one fuse element, wherein in the closed state a current flow between the at least one fuse element and the electrical component is uninterrupted and, in the triggered state, the current flow between the at least one fuse element and the electrical component is interrupted.

### PRIORITY CLAIM

This patent application is a U.S. National Phase of International Patent Application No. PCT/EP2024/060564, filed 18 Apr. 2024, which claims priority to German Patent Application No. 10 2023 203 791.2, filed 25 Apr. 2024, the disclosures of which are incorporated herein by reference in their entireties.

### FIELD

Illustrative embodiments relate to the field of safety devices for transportation vehicles. Specifically, illustrative embodiments relate to a device for a fuse box of a transportation vehicle, a fuse system, a transportation vehicle, and a method for operating such a device for a fuse box of a transportation vehicle.

### SUMMARY

Disclosed embodiments provide a device and a method which make it possible to read out a state, in particular a change of state, of a fuse element particularly quickly and reliably and at the same time to restore the current flow interrupted by the triggering of the fuse element quickly and easily. In particular, disclosed embodiments provide an improved device for a fuse box of a motor vehicle.

### BRIEF DESCRIPTION OF THE DRAWINGS

Disclosed embodiments will be described in more detail below with reference to drawings, in which:

FIG. 1 schematically shows a fuse system according to an disclosed embodiment;

FIG. 2 schematically shows a security system according to an disclosed embodiment;

FIG. 3 shows a flow diagram of a method according to an disclosed embodiment; and

FIG. 4 shows a transportation vehicle according to an disclosed embodiment.

### DETAILED DESCRIPTION

Transportation vehicles have a fuse box, which is used to protect electrical components from short circuits or overloads. In order to interrupt a current flow to the electrical component, the fuse box can have fusible elements, i.e., fuse elements that melt when the current load is too high. When such a fusible element is triggered, the fusible element must be replaced to restore the flow of current.

In DE 10 2012 021 558 A1, fuse elements are proposed that make it possible to restore the current flow without replacing the fuse.

Fusible elements also have the disadvantage that an interruption of the current flow can only be detected by removing the fusible element. In DE 20 2015 001 518 U1 it is proposed to indicate the state of the fuse by a visually perceptible display. DE 10 2012 021 506 A1 proposes a monitoring device that is arranged in the fuse box of the transportation vehicle and serves to detect the state of the fuse to send it to an external unit.

It is the objective of the present invention to provide a device and a method which make it possible to read out a state, in particular a change of state, of a fuse element particularly quickly and reliably and at the same time to restore the current flow interrupted by the triggering of the fuse element quickly and easily. In particular, the it is the objective of the present invention to provide an improved device for a fuse box of a transportation vehicle.

Further features and details of the disclosed embodiment can be found in the description and the drawings. In this context, features described in connection with the device naturally also apply in connection with the fuse system, the transportation vehicle and/or the method and vice versa in each case, so with regard to the disclosure of the individual aspects of the disclosed embodiment, reference is or can always can be made to each other.

A first aspect of the present disclosure relates to a device for a fuse box of a transportation vehicle. The device has at least one fuse element which can be coupled to the fuse box of the transportation vehicle, in particular at least indirectly, and which can be allocated to an electrical component of the transportation vehicle, a control unit and a display unit. The at least one fuse element is configured to assume a triggered state or a closed state. The control unit is configured to detect the state of the at least one fuse element and transmit it to the display unit. The display unit is configured to indicate a change in state, and in particular the current state, of the at least one fuse element. In the closed state, a current flow is uninterrupted, and in the triggered state, the current flow between the at least one fuse element and the electrical component is interrupted.

In other words, a device can be provided that makes it possible to determine by optical perception whether a fuse element has been triggered or not. The display unit can indicate, for example, by lights in a predefined color, the state of the at least one fuse element. The fuse element can basically assume two states: a closed state and a triggered state. The closed state can be called the default state. The triggered state usually refers to a condition in which the current flow between the fuse element and the electrical component of the transportation vehicle is interrupted due to a fault or because a limit is exceeded. The triggered state can therefore be called the fault state. The change from the default state to the fault state usually takes place automatically, for example, by the control unit. The change from the fault state back to the default state can also be done independently, or by the control unit.

In the context of the present disclosure, a change of state can denote a change into both the default state and out of the default state. In principle, the display unit can be set up such that it is possible at any time to determine by visual perception whether a change of state has taken place and/or how often a change of state has taken place and/or based on which state a change of state has taken place. For this purpose, it is conceivable that a color code can be defined for each possibility. A change of state starting from the default state can, for example, be indicated by the display unit by a first color. For example, a state change starting from the triggered state can be indicated by the display unit with a second color that differs from the first color.

The at least one fuse element can be coupled to the fuse box such that an electrical contact can be established between the electrical component, which is usually in electrical contact with the fuse box, and the fuse element. According to this, the fuse element can be electrically coupled to the fuse box, in particular it can be coupled indirectly. In order to couple the at least one fuse element to the fuse box, a connecting element may be provided for each fuse element.

The device may also have a housing. The device, if appropriate the housing, can be configured to be integrated into a fuse box or to be coupled to a fuse box.

The device can generally have several fuse elements. If there are several fuse elements, a display unit can be provided for each fuse element. Each of the several fuse elements can be allocated to an electrical component of the transportation vehicle.

The electrical component of the transportation vehicle can be, for example, an Anti-Lock Braking System (ABS), a radio, an airbag, a seat heating system, and/or a distance sensor.

Such a device allows the state of a fuse element to be indicated in a simple and reliable way and thus to be determined by a user. This eliminates the need for diagnostic devices.

According to at least one disclosed embodiment, the at least one fuse element is a semiconductor element.

According to at least one disclosed embodiment, the control unit is configured to control the at least one fuse element from the triggered state to the closed state. In other words, the control unit can reset the fuse to its original default state, wherein the default state corresponds to the closed state. In particular, the control unit may be configured to automatically control the return of the fuse element to the closed state, for example, automatically when the current level falls below a maximum level.

Depending on the electrical component, it can prove beneficial to automatically control the fuse element into the closed state by the control unit. For some electrical components, a command from a user may be required to cause the control unit to return the fuse element to the closed state. Such a command can be transmitted via a user interface. Whether or not the control unit can automatically or manually control the fuse element to the default state may depend on the allocated electrical component.

This means that the fuse element can be easily controlled back to the closed state, so that the current flow can also be easily restored.

According to at least one disclosed embodiment, the display unit is also configured to indicate a state of the at least one fuse element assumed at least for a short time, in particular a triggered state of the at least one fuse element assumed for a short time. In other words, the display unit may be designed or configured such that if at any time the fuse has returned to the triggered state, the display unit will continue to indicate this even after the fuse element has returned to the closed state. It is therefore conceivable that the display unit illuminates with a third color, such as orange, for example, if the current flow is uninterrupted again, but the fuse element has previously been triggered at least briefly. The display unit can therefore be configured to only indicate a change of state from the closed state to the triggered state.

Alternatively, the display unit can indicate different colors depending on the state of the fuse element from which the state change occurred.

According to at least one disclosed embodiment, the display unit is an LED. The LED can display different colors. This makes it possible to detect a change in state quickly and easily, and in particular the state of the fuse element. In other words, the display unit is optionally a small, low-power LED. The LED can be attached to the housing of the device. Optionally, the LED is mounted such that it is visually clearly visible to a user.

This can provide a simple yet highly reliable device for a fuse box of a transportation vehicle.

According to at least one disclosed embodiment, a user interface is also provided which is configured to detect an input from a user to control the display unit, in particular to unlock the display unit. The user interface is optionally a button or a reset button. By operating the user interface, the display unit can return to its default setting, for example, when it is indicating a change of state to the triggered state of the fuse element. The default setting can be a setting in which the display unit is able to indicate a change of state at any time.

A second aspect of the present disclosure relates to a fuse system for a transportation vehicle. The fuse system has a device as described above and below and a fuse box. The fuse box has at least one voltage input, which is allocated to an electrical component of the transportation vehicle.

The fuse box can be an EM box, an LVI or an HSB. All the benefits explained in connection with the device according to the first aspect of the present disclosure apply equally to the fuse system according to the second aspect of the present disclosure.

A third aspect of the present disclosure relates to a transportation vehicle having a fuse system as described above and below or a device as described above and below.

A fourth aspect of the present disclosure relates to a method for operating a device for a fuse box of a transportation vehicle as described above and below. The method has the following operations:
The at least one fuse element of the device assuming a triggered state or a closed state depending on a current flow between the at least one fuse element and the electrical component, and
The display unit of the device indicating the assumed state of the at least one fuse element of the device and/or a change of state of the at least one fuse element.

All the benefits explained in connection with the device according to the first aspect of the present disclosure and/or with the fuse system according to the second aspect of the present disclosure and/or with the transportation vehicle according to the third aspect of the present disclosure apply equally to the method according to the fourth aspect of the present disclosure.

According to at least one disclosed embodiment of the method, after changing the at least one fuse element from the triggered state back to the closed state, the display unit is locked such that it continues to indicate the triggered state. This can prove to be particularly beneficial if the fuse element is a semiconductor element because semiconductor elements, in contrast to fusible fuses, can switch on again automatically, in particular by a control unit, when the problem is eliminated. A temporary triggering due, for example, to undervoltage can then still be detected by locking the display unit or maintaining the display unit.

According to at least one disclosed embodiment of the method, the display unit is unlocked by a user interface, so that the display unit indicates the current state of the at least one fuse element.

According to at least one disclosed embodiment of the method of operating the user interface, the fuse element assumes the closed state.

All disclosures described above and below with respect to any aspect of the present disclosure apply equally to all other aspects of the present disclosure.

Similar, similarly working, identical or identically working elements are provided with similar or identical reference signs in the figures. The figures are merely schematic and not to scale.

FIG. 1 schematically shows a fuse system 200 according to a disclosed embodiment. The fuse system 200 has a device 100 for a fuse box 10 of a transportation vehicle 300 and the fuse box 10. The device 100 may be configured to be plugged into the fuse box 10 or to be coupled to the fuse box 10. The device 100 of FIG. 1 has two fuse elements 12, each of which is allocated to an electrical component of the transportation vehicle 300. Each of the two fuse elements 12 can be coupled to the fuse box 10, for example, via a respective connecting element 20, in particular electrically coupled. The fuse elements 12 are optionally semiconductor fuses. Each of the two fuse elements 12 can assume a triggered state, or a fault state, or a closed state, i.e., a default state. In the closed state, the current flow between the corresponding electrical component and the corresponding fuse element 12 may be uninterrupted. If a fault occurs, if a current occurs above a maximum permissible current, if a minimum voltage is not reached and/or if predefined boundary conditions are exceeded, the corresponding fuse element 12 can be triggered, so that the current flow between the fuse element 12 and the corresponding electrical component is interrupted.

For each of the two fuse elements 12, a display unit 14 is provided. Each of the two provided display units 14 can therefore be allocated to a fuse element 12 and thus to an electrical component. The display units 14 are optionally LEDs. Each display unit 14 is configured to indicate a change in state, and in particular a current state, of the respective allocated fuse element 12, in particular by visual perception.

The device 100 also has a control unit 13, which is configured to record the state of the respective fuse elements 12 and transmit it to the corresponding display unit 14, so that the display unit 14 can illuminate according to the state of the fuse element 12, for example.

Such a device 100 therefore enables the visual indication of the triggering state of semiconductor fuses. This makes it possible to eliminate the need for diagnostics even in safety-relevant applications. In addition, the display unit 14, or the trigger indicator, can continue to indicate that a triggered state has previously been assumed, at least for a short time, after automatic reactivation or after the default state has been resumed.

The device 100 may also have a user interface 16. The user interface 16 can be in the form of a manual reset. The user interface 16 can be a button in the housing of the device 100, or in a small recess or opening of the housing of the device 100. By operating the user interface 16, the control unit 13 may be prompted to optionally return all fuse elements 12 to the default state, i.e., (if appropriate) to close again. By operating the user interface 16, the control unit 13 can alternatively or additionally be prompted to unlock the display units 14 or to control them such that the display units 14 now indicate the current states of the fuse elements 12. Using the user interface 16, the fuse elements 12 can be manually reactivated. Alternatively or additionally, by the user interface 16, the display units 14 can again assume a default setting. The user interface 16 can be configured such that it can only be operated by a pointed object.

The fuse system 200 also has the fuse box 10. The fuse box 10 optionally has a voltage input 18 for each electrical component of the transportation vehicle 300. The fuse box 10 and The device 100 are optionally separable from each other.

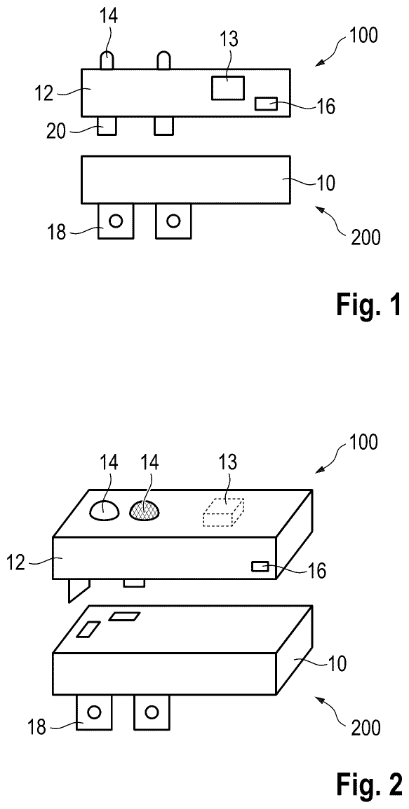

FIG. 2 schematically shows a fuse system 200 according to a disclosed embodiment. Unless otherwise described, the fuse system 200 of FIG. 2 has the same elements and/or components as the fuse system 200 of FIG. 1.

As shown in FIG. 2, the display units 14 can be small LEDS, which can light up differently depending on the state of the corresponding fuse element 12. Advantageously, each display unit 14 can light up in at least three different colors.

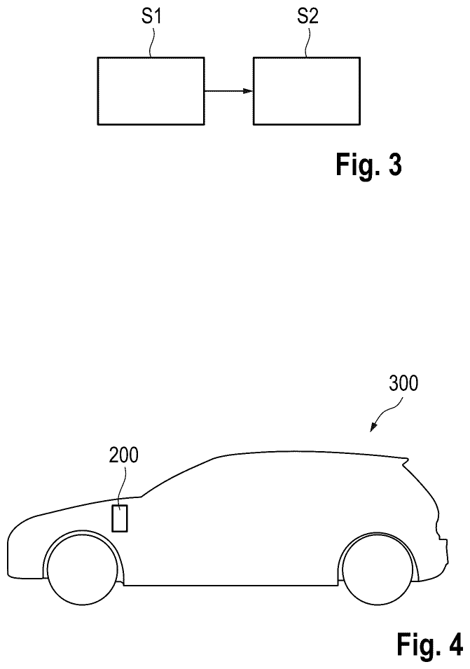

FIG. 3 shows a flow diagram of a method for operating a device 100 for a fuse box 10 of a transportation vehicle 300 according to a disclosed embodiment. In a first operation S1 of the method, the at least one fuse element 12 of the device 100 assumes a triggered state or a closed state. The fuse element 12 can assume the triggered state if a predefined boundary condition is exceeded or is not reached. The assumption of the triggered state can depend on a current value, a voltage value, and/or a conduction value, which can be detected by the control unit 13, for example. The fuse element 12 can therefore assume the triggered state depending on the current flow between the fuse element 12 and the electrical component.

In other words, in a first operation of the method, for example, by the control unit 13, it can be determined whether a fault has occurred. If a fault occurs, the fuse element 12 assumes the triggered state to interrupt the current flow for safety reasons. Subsequently, in a second operation S2 of the method, the display unit 14 will indicate the change of state and/or the assumed state of the fuse element 12, in particular by lighting up in a predefined color. In an optional operation of the method, the control unit 13 can record parameters of the current flow. In a further optional operation of the method, the control unit 13 can transmit the state of the fuse element 12 to the display unit 14.

After the fault has been corrected, or if the predefined boundary conditions have only been exceeded or undercut for a short time, the fuse element 12 can return to the default state independently, or the control unit 13 can initiate this. In order to still be able to inform the user about the short-term fault, it can prove to be particularly beneficial to lock the display unit 14 after a change of state from the closed state to the triggered state such that it continues to indicate the fault, even after the fuse element 12 has returned to the default state.

Alternatively, the display unit 14 can be locked such that it illuminates in a third color if the fuse element 12 has returned to the default state but has in the meantime assumed the triggered state. This allows the user to be informed particularly reliably about the state or the state history of the fuse element 12. To unlock the display unit 14, the user interface 16 can be operated by a user in a further operation of the method.

FIG. 4 shows a transportation vehicle 300 according to an disclosed embodiment. The transportation vehicle 300 has a fuse system 200. The transportation vehicle 300 can have an anti-lock braking system, a radio, an airbag, and/or seat heating as electrical components. The transportation vehicle 300 may have several fuse systems 200.

In addition, it should be noted that the terms “comprising” and “having” do not exclude any other elements, and the indefinite articles “a” or “an” do not exclude a plurality. It should also be noted that features and operations described by reference to one of the above disclosed embodiments may also be used in combination with other features and operations of other disclosed embodiments described above.

### LIST OF REFERENCE SIGNS

100 Device
200 Fuse System
300 Transportation vehicle
10 Fuse box
12 Fuse element
13 Control unit
14 Display unit
16 User Interface
18 Voltage input
20 Connecting element

1. A device for a fuse box of a motor vehicle, the device comprising:
at least one fuse element couplable to the fuse box of the motor vehicle and allocatable to an electrical component of the motor vehicle,
a control unit, and
a display unit,
wherein the at least one fuse element is configured to assume a triggered state or a closed state,
wherein the control unit is configured to detect the state of the at least one fuse element and transmit the state to the display unit,
wherein the display unit is configured to display a change in the state of the at least one fuse element,
wherein in the closed state a current flow between the at least one fuse element and the electrical component is uninterrupted and, in the triggered state, the current flow between the at least one fuse element and the electrical component is interrupted.

2. The device of claim 1, wherein the at least one fuse element is a semiconductor element.

3. The device of claim 1, wherein the control unit is configured to control the at least one fuse element from the triggered state to the closed state.

4. The device of claim 1, wherein the display unit is also configured to indicate a temporarily assumed state of the at least one fuse element.

5. The device of claim 1, wherein the display unit is an LED.

6. The device of claim 1, further comprising a user interface configured to detect an input of a user to control the display unit to unlock the display unit.

7. A fuse system for a motor vehicle, comprising the device of claim 1 and a fuse box, wherein the fuse box has at least one voltage input allocated to an electrical component of the motor vehicle.

8. A motor vehicle comprising the fuse system of claim 7.

9. A method for operating a device for a fuse box of a motor vehicle the device including at least one fuse element couplable to the fuse box of the motor vehicle and allocatable to an electrical component of the motor vehicle, a control unit, and a display unit, wherein the at least one fuse element is configured to assume a triggered state or a closed state, wherein the control unit is configured to detect the state of the at least one fuse element and transmit the state to the display unit, wherein the display unit is configured to display a change in the state of the at least one fuse element,
the method comprising:
the at least one fuse element of the device assuming a triggered state or a closed state depending on a current flow between the at least one fuse element and the electrical component, and
the display unit of the device displaying the assumed state of the at least one fuse element of the device and/or a change of state of the at least one fuse element, wherein in the closed state a current flow between the at least one fuse element and the electrical component is uninterrupted and, in the triggered state, the current flow between the at least one fuse element and the electrical component is interrupted.

10. The method of claim 9, wherein, after changing the at least one fuse element from the triggered state back to the closed state, the display unit is locked such that the display unit continues to display the triggered state.

11. The method of claim 9, wherein the display unit is unlocked a user interface so that the display unit displays the current state of the at least one fuse element.

12. The method of claim 9,
wherein, in response to activation of the user interface, the fuse element assumes the closed state.
